(19) United States
(12) Patent Application Publication
(10) Pub. No.: US 2023/0352390 A1
(43) Pub. Date: Nov. 2, 2023

(54) PACKAGE COMPRISING A SUBSTRATE WITH A BUMP PAD INTERCONNECT COMPRISING A TRAPEZOID SHAPED CROSS SECTION

(71) Applicant: QUALCOMM Incorporated, San Diego, CA (US)

(72) Inventors: Chin-Kwan KIM, San Diego, CA (US); Joan Rey Villarba BUOT, Escondido, CA (US); Zhijie WANG, San Diego, CA (US); Marcus HSU, San Diego, CA (US); Sang-Jae LEE, San Diego, CA (US); Kuiwon KANG, San Diego, CA (US)

(21) Appl. No.: 17/735,075

(22) Filed: May 2, 2022

(51) Int. Cl. H01L 23/498; H01L 23/00; H01L 21/48

(52) U.S. Cl. CPC H01L 23/49838; H01L 24/16; H01L 24/81; H01L 21/4857; H01L 2224/16227; H01L 2224/16237; H01L 24/32; H01L 2224/32237; H01L 24/73; H01L 2224/73204; H01L 24/83; H01L 2224/83192; H01L 2224/81815; H01L 2224/81203; H01L 2224/81385; H01L 23/49822

(57) ABSTRACT

A package comprising a substrate and an integrated device coupled to the substrate. The substrate includes at least one dielectric layer and a plurality of interconnects comprising a bump pad interconnect. The bump pad interconnect comprises a profile cross section that has a trapezoid shape. The integrated device is coupled to the substrate through the bump pad interconnect. The bump pad interconnect is located in a cavity of the at least one dielectric layer of the substrate.

### FIELD

Various features relate to packages with a substrate.

### BACKGROUND

A package may include a substrate and integrated devices. These components are coupled together to provide a package that may perform various electrical functions. Joints in a package may affect the performance of a package. There is an ongoing need to improve the joints in a package. Moreover, there is an ongoing need to provide better performing packages.

### SUMMARY

Various features relate to packages with a substrate.

One example provides a package comprising a substrate and an integrated device coupled to the substrate. The substrate includes at least one dielectric layer and a plurality of interconnects comprising a bump pad interconnect. The bump pad interconnect comprises a profile cross section that has a trapezoid shape.

Another example provides an apparatus that includes a package. The package includes a substrate and an integrated device coupled to the substrate. The substrate includes at least one dielectric layer comprising a cavity, where the cavity includes a cavity width. The substrate includes a plurality of interconnects comprising a bump pad interconnect. The bump pad interconnect includes a first portion comprising a first width, where the first width is less than the cavity width. The bump pad interconnect includes a second portion comprising a second width that is greater than the first width, where the bump pad interconnect is located in the cavity of the at least one dielectric layer.

Another example provides a method for fabricating a substrate. The method provides at least one dielectric layer. The method forms a plurality of interconnects. Forming the plurality of interconnects comprises forming a bump pad interconnect that includes a profile cross section comprising a trapezoid shape.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross-sectional profile view of a package that includes a substrate with a bump pad interconnect.

FIG. 2 illustrates an exemplary view of a bump pad interconnect.

FIG. 3 illustrates an exemplary cross-sectional profile view of a substrate with a bump pad interconnect.

FIG. 4 illustrates an exemplary plan view of a substrate with a bump pad interconnect.

FIG. 5 illustrates an exemplary cross-sectional profile view of a substrate with a bump pad interconnect.

FIG. 6 illustrates an exemplary plan view of a substrate with a bump pad interconnect.

FIG. 7 illustrates an exemplary cross-sectional profile view of a substrate with a bump pad interconnect.

FIG. 8 illustrates an exemplary plan view of a substrate with a bump pad interconnect.

FIGS. 9A-9C illustrate an exemplary sequence for fabricating a substrate with a bump pad interconnect.

FIG. 10 illustrates an exemplary flow chart of a method for fabricating a substrate with a bump pad interconnect.

FIGS. 11A-11B illustrate an exemplary sequence for fabricating a package that includes a substrate with a bump pad interconnect.

FIG. 12 illustrates an exemplary flow chart of a method for fabricating a package that includes a substrate with a bump pad interconnect.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package that includes a substrate and an integrated device coupled to the substrate. The substrate includes at least one dielectric layer and a plurality of interconnects comprising at least one bump pad interconnect. The bump pad interconnect comprises a profile cross section that has a trapezoid shape. The bump pad interconnect is located in a cavity of the at least one dielectric layer. The integrated device is coupled to the substrate through a solder interconnect and the bump pad interconnect from a plurality of bump pad interconnects. The bump pad interconnect is located in a cavity of the at least one dielectric layer of the substrate. The use of bump pad interconnect with a trapezoid shaped profile cross section helps reduce and/or minimize underfill that may be trapped between the bump pad interconnect and a solder interconnect. An underfill between the bump pad interconnect and a solder interconnect can cause a weak joint and/or an unreliable joint between the integrated device and the substrate. This can cause tearing and/or poor performance of the package. By reducing, minimizing, and/or eliminating underfill (and/or filler, particles from the underfill) between the bump pad interconnect and a solder interconnect, a stronger and/or more reliable joint is provided that is less likely to tear, which can result in improved package performance and/or improved integrated device performance.

Exemplary Package Comprising a Substrate with a Bump Pad Interconnect Comprising a Trapezoid Shaped Profile Cross Section

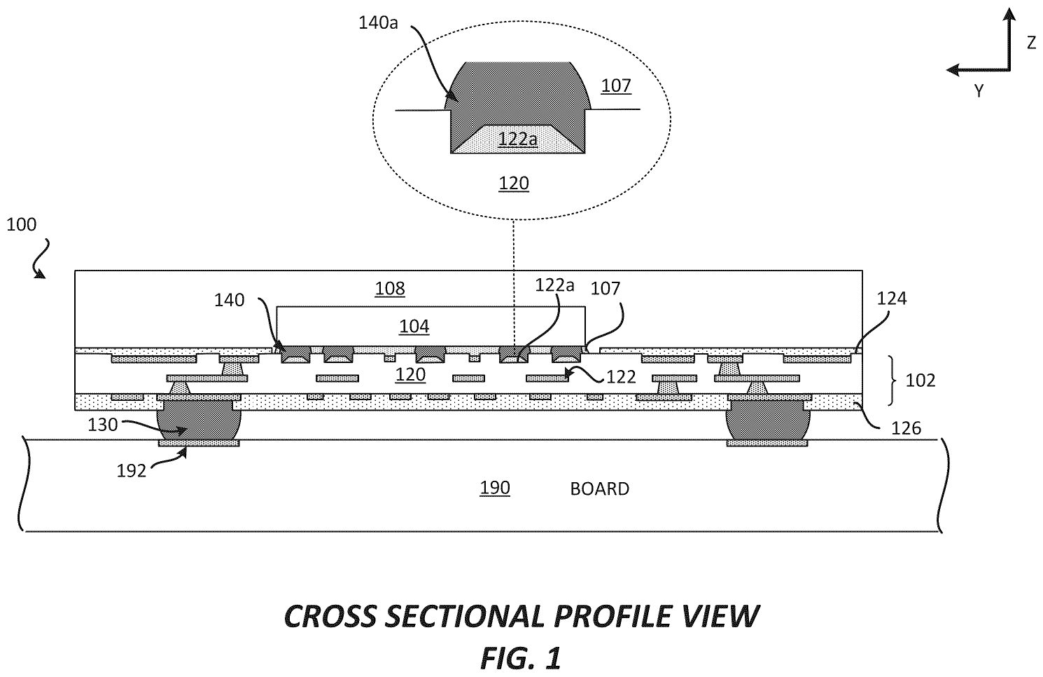

FIG. 1 illustrates a cross-sectional profile view of a package 100 that includes a substrate with a bump pad interconnect comprising a trapezoid shaped profile cross section. The package 100 includes a substrate 102, an integrated device 104, an underfill 107, and an encapsulation layer 108. The package 100 is coupled to a board 190 (e.g., printed circuit board) through a plurality of solder interconnects 130. The board 190 includes a plurality of board interconnects 192. The package 100 is coupled to the plurality of board interconnects 192 through the plurality of solder interconnects 130.

The substrate 102 includes at least one dielectric layer 120, a plurality of interconnects 122, a solder resist layer 124, and a solder resist layer 126. The substrate 102 may be a coreless substrate (e.g., embedded trace substrate (ETS)). The substrate 102 may include a first surface (e.g., top surface) and a second surface (e.g., bottom surface). The solder resist layer 124 may be located over the first surface of the substrate 102. The solder resist layer 126 may be located over the second surface of the substrate 102. The plurality of interconnects 122 includes a bump pad interconnect 122a. A bump pad interconnect is an interconnect that is configured to be coupled to a solder interconnect. The bump pad interconnect may be an interconnect from a substrate that an integrated device (or other device) is coupled through a solder interconnect and/or pillar interconnect. The bump pad interconnect 122a may be located over the first surface (e.g., top surface) of the substrate 102. As will be further described below, the bump pad interconnect 122a may include a trapezoid shaped profile cross section. The bump pad interconnect 122a may be a bump pad interconnect from a plurality of bump pad interconnects. The plurality of bump pad interconnects may include other bump pad interconnects with similar or different shapes as the bump pad interconnect 122a. The bump pad interconnect 122a may include a first portion and a second portion. The first portion may be a top portion, and the second portion may be second portion. The second portion of the bump pad interconnect 122a has a second width that is greater than a first width of the first portion of the bump pad interconnect 122a. The first portion of the bump pad interconnect 122a has a first width that is less than a second width of the second portion of the bump pad interconnect 122a. The bump pad interconnect 122a includes a diagonal surface. The diagonal surface of the bump pad interconnect 122a may be diagonal to a surface of the at least one dielectric layer 120 (e.g., diagonal to a side surface/side wall of a cavity in the at least one dielectric layer 120, diagonal to horizontal and/or planar surface of the at least one dielectric layer 120). As will be further described below, the bump pad interconnect 122a is located in a cavity of the at least one dielectric layer 120. The bump pad interconnect 122a may recessed from a surface (e.g., top planar surface) of the at least one dielectric layer 120.

The integrated device 104 is coupled to a first surface (e.g., top surface) of the substrate 102 through a plurality of solder interconnects 140. For example, the integrated device 104 is coupled to the plurality of interconnects 122 of the substrate 102 through the plurality of solder interconnects 140. In particular, the integrated device 104 is coupled to the bump pad interconnect 122a through a solder interconnect 140a from the plurality of solder interconnects 140. It is noted that the integrated device 104 may be coupled to a plurality of bump pad interconnects (e.g., other bump pad interconnects similar in shape and/or size as the bump pad interconnect 122a) through a plurality of solder interconnects 140. The underfill 107 is located between the integrated device 104 and the substrate 102. The underfill 107 may include a non-conducting paste (NCP). The underfill 107 may include filler and/or particles. During a process of coupling the integrated device 104 to the substrate 102, some of the underfill 107 may be trapped between the plurality of solder interconnects 140 and bump pad interconnects (e.g., 122a). Underfill between the bump pad interconnect and a solder interconnect can cause a weak joint and/or an unreliable joint between the integrated device and the substrate. For example, underfill between a bump pad interconnect and a solder interconnect can cause solder tearing. The more underfill there is between a bump pad interconnect and a solder interconnect, the more likely there is going to be solder tearing. This can cause poor performance of the package and/or a defective package. By reducing, minimizing, and/or eliminating underfill (and/or filler, particles from the underfill) between a bump pad interconnect and a solder interconnect, a stronger and/or more reliable joint is provided that is less likely to tear, which can result in improved package performance and/or improved integrated device performance.

The encapsulation layer 108 is provided (e.g., formed) over the first surface of the substrate 102. The encapsulation layer 108 is coupled to the substrate 102. The encapsulation layer 108 may encapsulate the integrated device 104. The encapsulation layer 108 may include a mold, a resin and/or an epoxy. A compression molding process, a transfer molding process, or a liquid molding process may be used to form the encapsulation layer 108. The encapsulation layer 108 may be photo etchable. The encapsulation layer 108 may be a means for encapsulation.

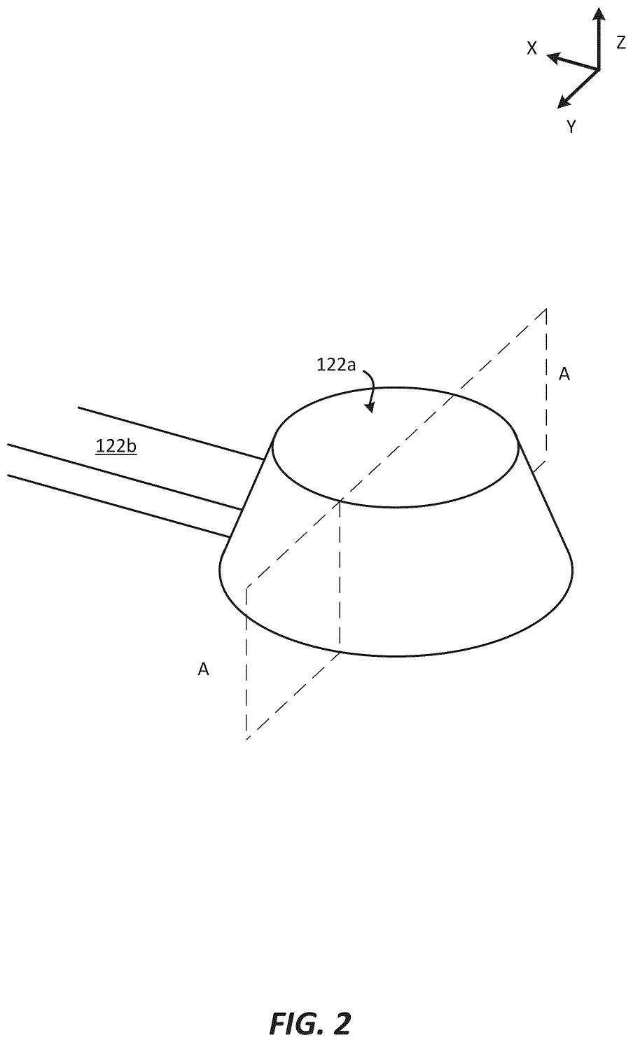

FIG. 2 illustrates an exemplary view of a bump pad interconnect with a trapezoid shaped profile cross section. FIG. 2 illustrates the bump pad interconnect 122a coupled to a trace interconnect 122b. The trace interconnect 122b may be an interconnect from the plurality of interconnects 122.

The bump pad interconnect 122a includes a first portion (e.g., top portion) and a second portion (e.g., bottom portion). The second portion is coupled to the first portion. The first portion and the second portion may be continuous and/or contiguous. The second portion of the bump pad interconnect 122a is coupled to the trace interconnect 122b. The first portion has a first width (e.g., first diameter), and the second portion has a second width (e.g., second diameter). The second width is different than the first width. The second width is greater than the first width. The first portion of the bump pad interconnect 122a has a planar cross-sectional shape of a first circle (e.g., first circular planar cross-section). The second portion of the bump pad interconnect 122a has a planar cross-sectional shape of a second circle (e.g., second circular planar cross-section). The second circle has a larger size than the first circle. A solder interconnect may be coupled to the first portion and/or the second portion of the bump pad interconnect 122a. An A-A profile cross section across the bump pad interconnect 122a has a trapezoid shape. The A-A profile cross section may extend through a Y-Z plane. Different implementations may define a profile cross section differently. A profile cross section may extend through a Y-Z plane and/or a X-Z plane.

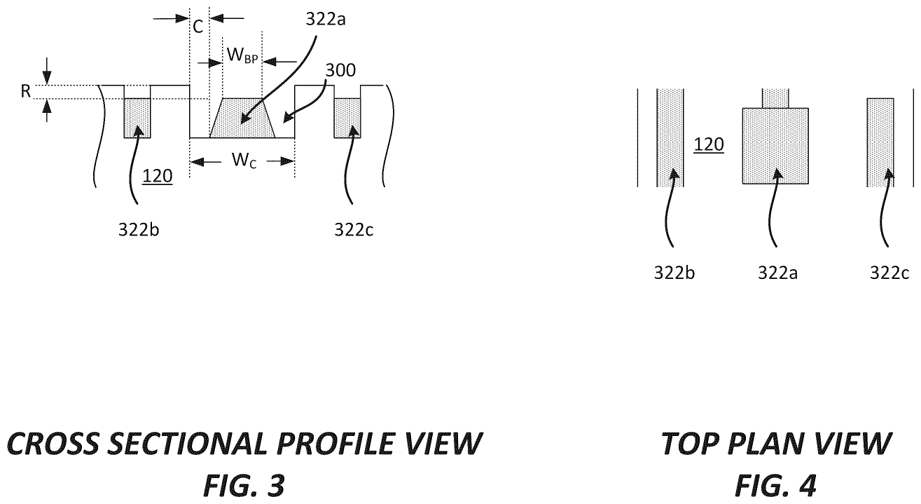

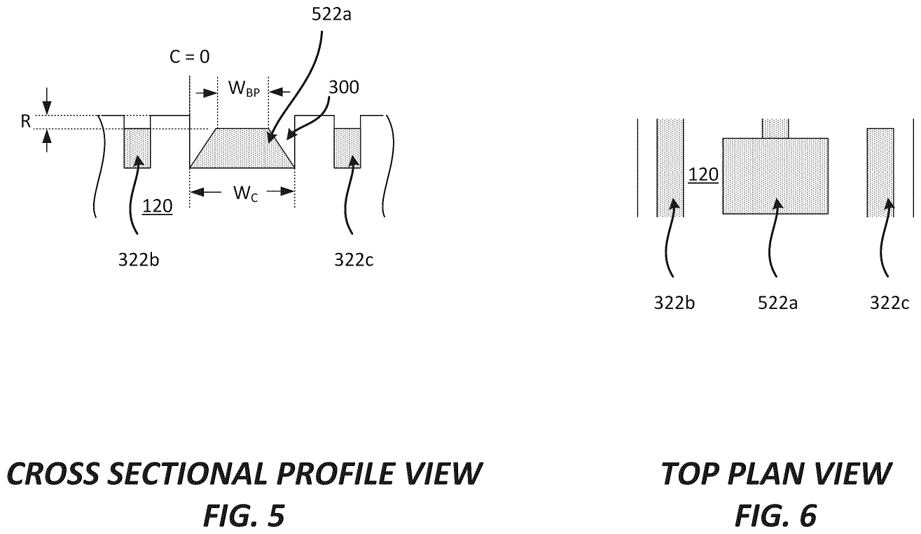

FIGS. 3 and 4 illustrate exemplary views of a bump pad interconnect in a substrate. FIGS. 3 and 4 may be close up views of the substrate 102 of FIG. 1. FIG. 3 illustrates a cross sectional profile view of a substrate that includes at least one dielectric layer 120, a bump pad interconnect 322a, an interconnect 322b and an interconnect 322c. FIG. 4 illustrates a top plan view of a substrate that includes at least one dielectric layer 120, the bump pad interconnect 322a, the interconnect 322h and the interconnect 322c. The bump pad interconnect 322a may be located between the interconnect 322b and the interconnect 322c. The bump pad interconnect 322a may be an example of the bump pad interconnect 122a.

The at least one dielectric layer 120 includes a cavity 300. The bump pad interconnect 322a may be located in the cavity 300 of the at least one dielectric layer 120. The cavity 300 includes a cavity width (Wc). As shown in FIG. 3, the bump pad interconnect 322a may be recessed from a surface (e.g., top surface) of the at least one dielectric layer 120 by a recess (R). A recess for an interconnect may be a distance between (i) a top portion of the interconnect in a cavity (e.g., 300) of the at least one dielectric layer 120 and (ii) a top surface of the at least one dielectric layer 120. In some implementations, the recess (R) may be in a range of about 2-6 micrometers (e.g., 4±2 micrometers). The interconnect 322b and the interconnect 322c are also recessed from a surface of the at least one dielectric layer 120 by a recess (R).

As further shown in FIG. 3, a first portion (e.g., top portion, highest top portion, first surface, top surface) of the bump pad interconnect 322a includes a width (Wbp) in a range of about 10-30 micrometers. The first portion (e.g., top portion, highest top portion, first surface, top surface) may have a width that is less than the cavity width (Wc) of the cavity 300. A second portion (e.g., bottom portion, lowest bottom portion, second surface, bottom surface) may have a width that is less than the cavity width (Wc) of the cavity 300.

As further shown in FIG. 3, the bump pad interconnect 322a is free of direct contact with a side wall and/or a side surface of the cavity 300. There is a clearance (C) of about 0.5-10 micrometers between a side of the bump pad interconnect 322a and a side wall and/or a side surface of the cavity 300. In some implementations, the clearance (C) is 0, meaning that at least a portion of the bump pad interconnect 322a may be in direct contact with a side wall and/or a side surface of the cavity 300. In some implementations, there may be an underfill and/or an encapsulation layer that is located in the cavity 300.

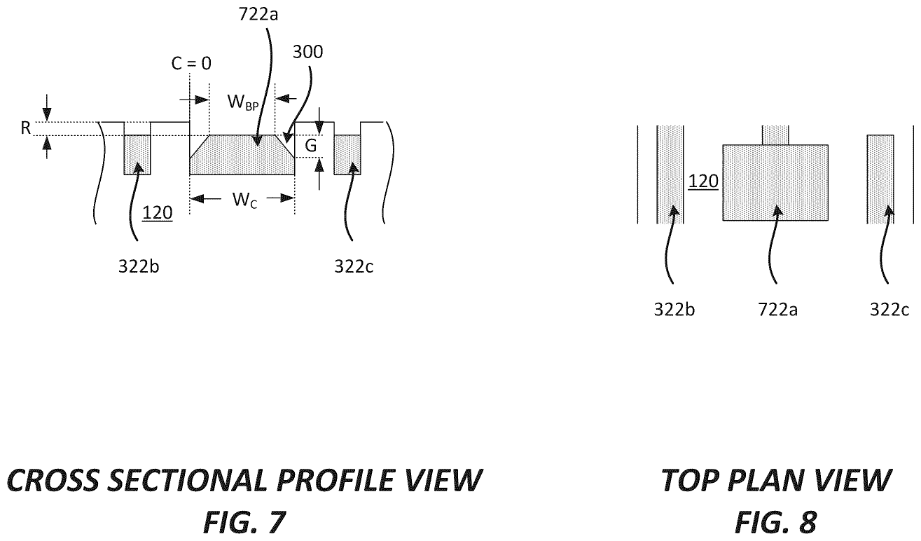

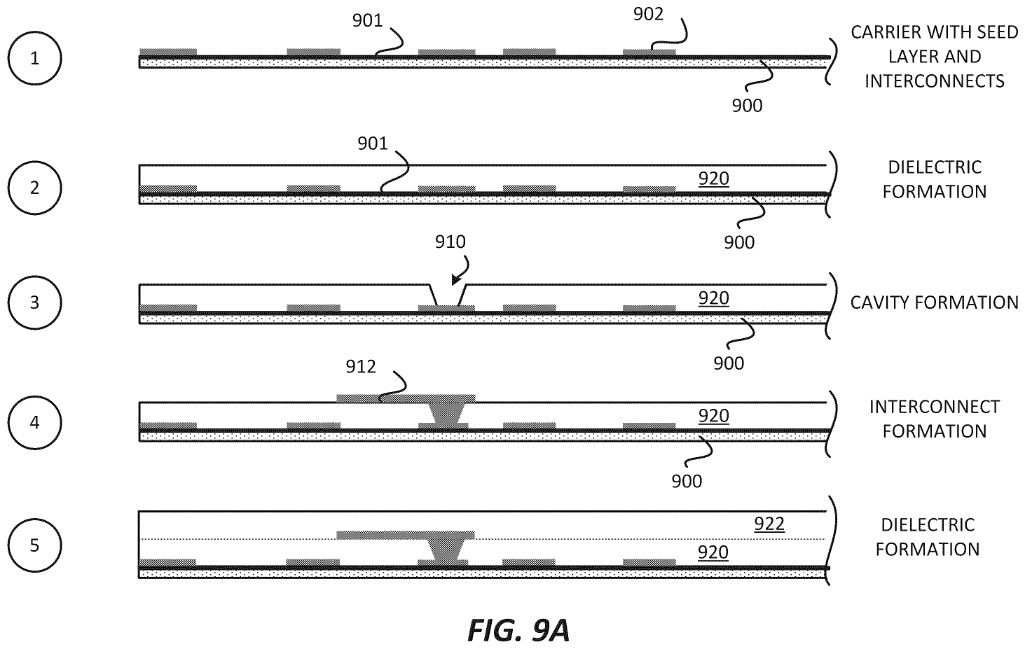

FIGS. 5 and 6 illustrate exemplary views of a bump pad interconnect in a substrate. FIGS. 5 and 6 may be close up views of the substrate 102 of FIG. 1. FIG. 5 illustrates a cross sectional profile view of a substrate that includes at least one dielectric layer 120, a bump pad interconnect 522a, the interconnect 322b and the interconnect 322c. FIG. 6 illustrates a top plan view of a substrate that includes at least one dielectric layer 120, the bump pad interconnect 522a, the interconnect 322b and the interconnect 322c. The bump pad interconnect 522a may be located between the interconnect 322b and the interconnect 322c. FIGS. 5 and 6 may be similar to FIGS. 3 and 4, and thus include similar components as FIGS. 3 and 4. FIGS. 5 and 6 illustrate a bump pad interconnect 522a with a different design and/or configuration than the bump pad interconnect 322a of FIGS. 3 and 4. The bump pad interconnect 522a may be an example of the bump pad interconnect 122a.

As shown in FIG. 5, the at least one dielectric layer 120 includes the cavity 300. The bump pad interconnect 522a may be located in the cavity 300 of the at least one dielectric layer 120. The cavity 300 includes a cavity width (Wc). As shown in FIG. 5, the bump pad interconnect 522a may be recessed from a surface (e.g., top surface) of the at least one dielectric layer 120 by a recess (R). In some implementations, the recess (R) may be in a range of about 2-6 micrometers (e.g., 4±2 micrometers).

As further shown in FIG. 5, a first portion (e.g., top portion, highest top portion, first surface, top surface) of the bump pad interconnect 522a includes a width (Wbp) in a range of about 10-30 micrometers. The first portion (e.g., top portion, highest top portion, first surface, top surface) may have a width that is less than the cavity width (Wc) of the cavity 300. A second portion (e.g., bottom portion, lowest bottom portion, second surface, bottom surface) may have a width that is the same as the cavity width (Wc) of the cavity.

As further shown in FIG. 5, portions (e.g., top portion, highest top portion) of the bump pad interconnect 322a are free of direct contact with a side wall and/or a side surface of the cavity 300. There is no clearance (C) between a side of the bump pad interconnect 522a and a side wall and/or a side surface of the cavity 300. In the implementations, the clearance (C) is 0, meaning that at least a portion (e.g., bottom portion, lowest bottom portion) of the bump pad interconnect 322a may be in direct contact with a side wall and/or a side surface of the cavity 300.

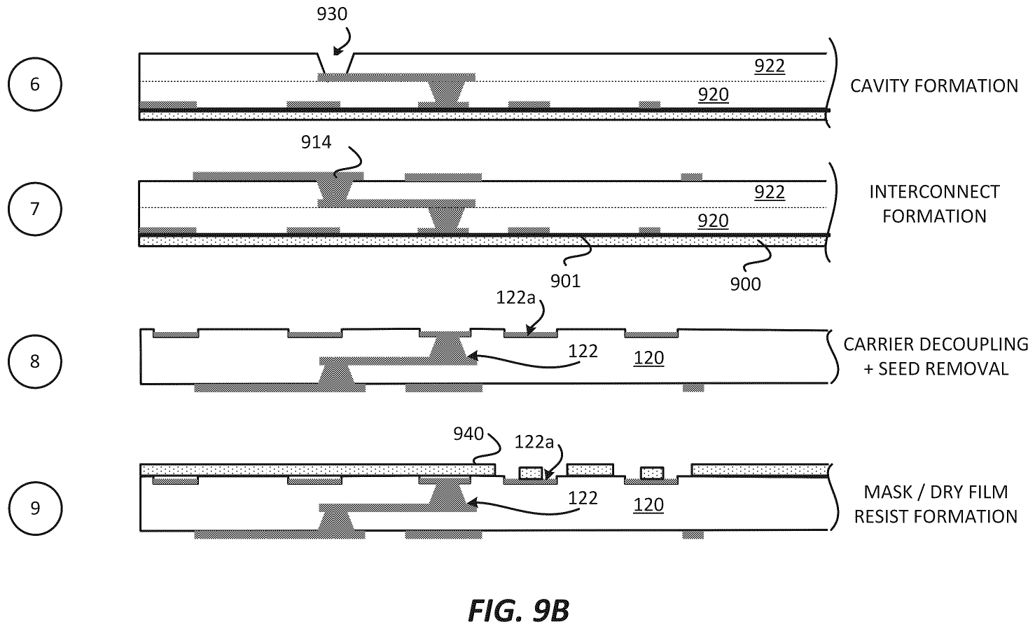

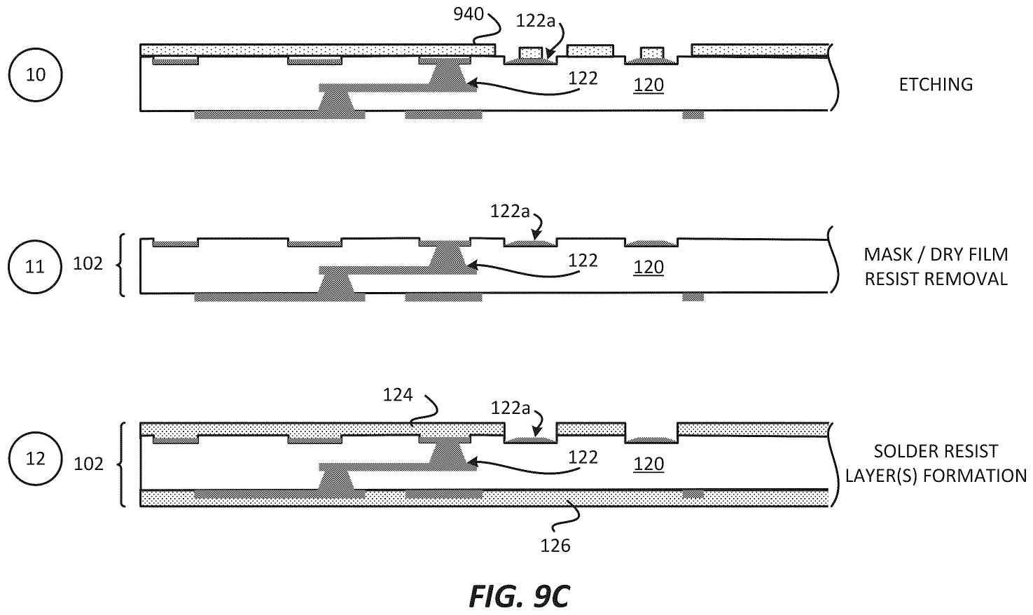

FIGS. 7 and 8 illustrate exemplary views of a bump pad interconnect in a substrate. FIGS. 7 and 8 may be close up views of the substrate 102 of FIG. 1. FIG. 7 illustrates a cross sectional profile view of a substrate that includes at least one dielectric layer 120, a bump pad interconnect 722a, the interconnect 322b and the interconnect 322c. FIG. 8 illustrates a top plan view of a substrate that includes at least one dielectric layer 120, the bump pad interconnect 722a, the interconnect 322b and the interconnect 322c. The bump pad interconnect 722a may be located between the interconnect 322b and the interconnect 322c. FIGS. 7 and 8 may be similar to FIGS. 3 and 4, and thus include similar components as FIGS. 3 and 4. FIGS. 7 and 8 illustrate a bump pad interconnect 722a with a different design and/or configuration than the bump pad interconnect 322a of FIGS. 3 and 4. The bump pad interconnect 722a may be an example of the bump pad interconnect 122a.

As shown in FIG. 7, the at least one dielectric layer 120 includes the cavity 300. The bump pad interconnect 722a may be located in the cavity 300 of the at least one dielectric layer 120. The cavity 300 includes a cavity width (Wc). As shown in FIG. 7, the bump pad interconnect 722a may be recessed from a surface (e.g., top surface) of the at least one dielectric layer 120 by a recess (R). In some implementations, the recess (R) may be in a range of about 2-6 micrometers (e.g., 4±2 micrometers).

As further shown in FIG. 7, a first portion (e.g., top portion, highest top portion, first surface, top surface) of the bump pad interconnect 722a includes a width (Wbp) in a range of about 10-30 micrometers. The first portion (e.g., top portion, highest top portion, first surface, top surface) may have a width that is less than the cavity width (Wc) of the cavity 300. A second portion (e.g., bottom portion, lowest bottom portion, second surface, bottom surface) may have a width that is the same as the cavity width (Wc) of the cavity.

As further shown in FIG. 7, portions (e.g., top portion, highest top portion) of the bump pad interconnect 322a are free of direct contact with a side wall and/or a side surface of the cavity 300. There is no clearance (C) between a side of the bump pad interconnect 722a and a side wall and/or a side surface of the cavity 300. In the implementations, the clearance (C) is 0, meaning that at least a portion (e.g., bottom portion, lowest bottom portion) of the bump pad interconnect 322a may be in direct contact with a side wall and/or a side surface of the cavity 300.

As further shown in FIG. 7, there is a gap (G) between a top portion of the bump pad interconnect 722a and a portion of the bump pad interconnect 722a that is in director contact with a side wall and/or side surface of the cavity 300. In some implementations, the gap (G) is in a range of about 2-10 micrometers.

Table 1 below, illustrates exemplary values for the various dimensions described above.

TABLE 1
Exemplary Values of Bump Pad Interconnects

| | DESIGN 1 | DESIGN 2 | DESIGN 3 |
|---|---|---|---|
| RECESS (R) | 4 ± 2 | 4 ± 2 | 4 ± 2 |
| | micrometers | micrometers | micrometers |
| TOP WIDTH | 10-30 | 10-30 | 10-30 |
| (WBP) | micrometers | micrometers | micrometers |
| CLEARANCE (C) | 0-30 | N/A | N/A |
| | micrometers | | |
| GAP (G) | N/A | N/A | 2-10 |
| | | | micrometers |

It should be noted that Table 1 is exemplary and a bump pad interconnect and the cavity that includes the bump pad interconnect may have other values. The design 1 values may correspond to FIGS. 3 and 4. The design 2 values may correspond to FIGS. 5 and 6. The design 3 values may correspond to FIGS. 7 and 8. The above values may help provide joints between an integrated device and a substrate, that are strong, more reliable, and/or less likely to tear, which can result in improved package performance and/or improved integrated device performance.

An integrated device (e.g., 104) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 103) may include at least one electronic circuit (e.g., first electronic circuit, second electronic circuit, etc. . . . ). An integrated device may include transistors. An integrated device may be an example of an electrical component and/or electrical device. In some implementations, an integrated device may include a chiplet. A chiplet may be fabricated using one or more processes that provides better yields compared to other processes that are used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

The package (e.g., 100) may be implemented in a radio frequency (RF) package. The RF package may be a radio frequency front end (RFFE) package. A package (e.g., 100, 300) may be configured to provide Wireless Fidelity (WiFi) communication and/or cellular communication (e.g., 2G, 3G, 4G, 5G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

Having described various packages with various substrates, a method for fabricating a substrate will now be described below.

Exemplary Sequence for Fabricating a Substrate Comprising a Bump Pad Interconnect with a Trapezoid Shaped Profile Cross Section

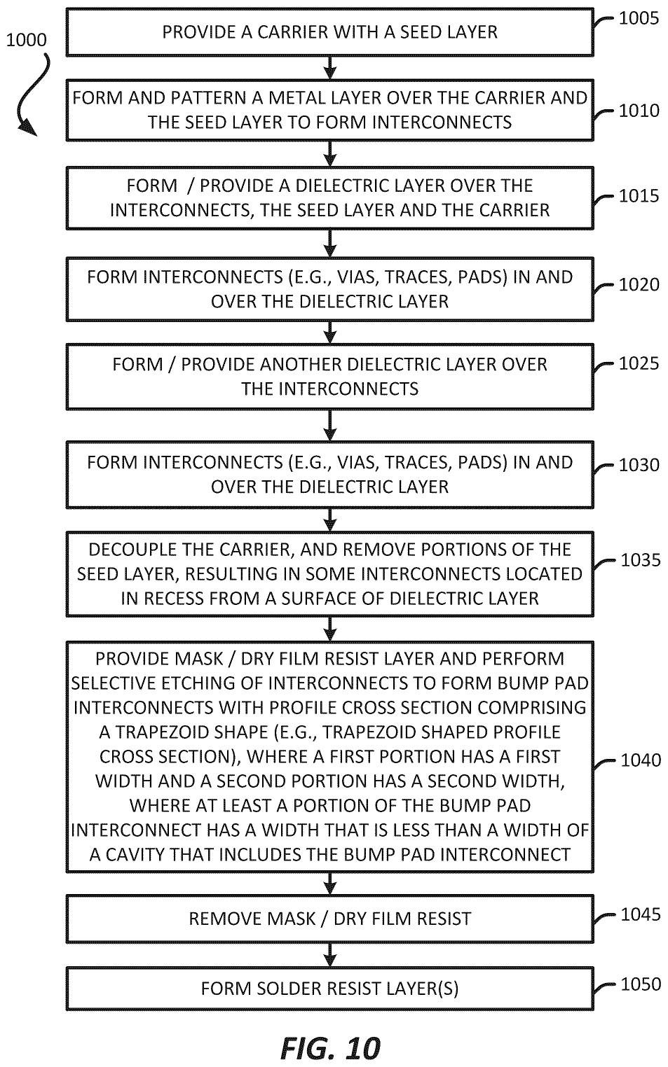

In some implementations, fabricating a substrate includes several processes. FIGS. 9A-9C illustrate an exemplary sequence for providing or fabricating a substrate that includes a bump pad interconnect. In some implementations, the sequence of FIGS. 9A-9C may be used to provide or fabricate the substrate 102. However, the process of FIGS. 9A-9C may be used to fabricate any of the substrates described in the disclosure.

It should be noted that the sequence of FIGS. 9A-9C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 9A, illustrates a state after a carrier 900 is provided. A seed layer 901 and interconnects 902 may be located over the carrier 900. The interconnects 902 may be located over the seed layer 901. A masking process, a plating process and etching process may be used to form the interconnects 902. In some implementations, the carrier 900 may be provided with the seed layer 901 and a metal layer that is patterned to form the interconnects 902. The interconnects 902 may represent at least some of the interconnects from the plurality of interconnects 122. The interconnects 902 may include an interconnect that represent portions of a pad interconnect (e.g., bump pad interconnect).

Stage 2 illustrates a state after a dielectric layer 920 is formed over the carrier 900, the seed layer 901 and the interconnects 902. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

Stage 3 illustrates a state after a plurality of cavities 910 is formed in the dielectric layer 920. The plurality of cavities 910 may be formed using an etching process (e.g., photo etching process) and/or laser process.

Stage 4 illustrates a state after interconnects 912 are formed in and over the dielectric layer 920, including in and over the plurality of cavities 910. For example, a via, pad and/or traces may be formed. A masking process, a plating process and/or an etching process may be used to form the interconnects.

Stage 5 illustrates a state after a dielectric layer 922 is formed over the dielectric layer 920 and the interconnects 912. A deposition and/or lamination process may be used to form the dielectric layer 922. The dielectric layer 922 may include prepreg and/or polyimide. The dielectric layer 922 may include a photo-imageable dielectric. However, different implementations may use different materials for the dielectric layer.

Stage 6, as shown in FIG. 9B, illustrates a state after a plurality of cavities 930 are formed in the dielectric layer 922. The plurality of cavities 930 may be formed using an etching process (e.g., photo etching process) and/or laser process.

Stage 7 illustrates a state after interconnects 914 are formed in and over the dielectric layer 922, including in and over the plurality of cavities 930. For example, a via interconnect, a pad interconnect and/or trace interconnects may be formed. A masking process, a plating process and/or an etching process may be used to form the interconnects. The plurality of interconnects 902, the plurality of interconnects 912, and/or the plurality of interconnects 914 may be represented by the plurality of interconnects 122. The dielectric layer 920 and/or the dielectric layer 922 may be represented by the at least one dielectric layer 120. The at least one dielectric layer 120 may include a photo-imageable dielectric. The at least one dielectric layer 120 may include prepreg and/or polyimide. It is noted that additional dielectric layers and interconnects may be formed by iteratively performing stages 5-7.

Stage 8 illustrates a state after the carrier 900 is decoupled (e.g., detached, removed, grinded out) from the at least one dielectric layer 120 and the seed layer 901, portions of the seed layer 901 are removed (e.g., etched out), leaving the substrate 102 that includes the at least one dielectric layer 120 and the plurality of interconnects 122. Some of the interconnects 122 may be located in cavities of the at least one dielectric layer 120. For example, the bump pad interconnect 122a may be located in a cavity of the at least one dielectric layer 120. The cavity is formed through a first surface of the at least one dielectric layer 120. The bump pad interconnect 122a may have the same width as the width of the cavity. The bump pad interconnect 122a may be recessed from the top surface of the at least one dielectric layer 120.

Stage 9 illustrates a state after a mask 940 is formed over the at least one dielectric layer 120 (e.g., a top surface of the at least one dielectric layer 120). A deposition and/or a lamination process may be used to form the mask 940 over a surface of the at least one dielectric layer 120. A mask 940 may be formed over a portion of the bump pad interconnect 122a, leaving portions of the bump pad interconnect 122a and portions of the bump pad interconnect 122a exposed. The mask 940 may include a dry film resist (DFS).

Stage 10, as shown in FIG. 9C, illustrates a state after portions of bump pad interconnects are removed (e.g., portion of the bump pad interconnect 122a are removed). An etching process may be used to remove portions of the bump pad interconnect 122a. The etching process may include a chemical etching process. Different implementations may remove a different amount of the portion of the bump pad interconnects. The etching process may include partial etching and/or full etching. The etching of the bump pad interconnect 122a (or any other bump pad interconnects) may form and define a bump pad interconnect that includes a trapezoid shaped profile cross section (e.g., bump pad interconnect that includes a profile cross section that has a shape of trapezoid), as described above in at least FIGS. 2-8. A portion of the bump pad interconnect may have a width that is less than the width of the cavity in which the bump pad interconnect is located in. Some portion (e.g., side portion) of the bump pad interconnect is free of direct contact with a side wall and/or side surface of the cavity in which the bump pad interconnect is located in.

Stage 11 illustrates a state after the mask 940 is removed. A decoupling process may be used to remove the mask 940.

Stage 12 illustrates a state after the solder resist layer 124 is formed over the at least one dielectric layer 120. A deposition process may be used to form the solder resist layer 124 and/or the solder resist layer 126. Stage 12 may illustrate a substrate 102 that includes at least one dielectric layer 120, a bump pad interconnect 122a (that includes a trapezoid shaped profile cross section), a solder resist layer 124 and a solder resist layer 126.

Different implementations may use different processes for forming the metal layer(s). In some implementations, a chemical vapor deposition (CVD) process and/or a physical vapor deposition (PVD) process for forming the metal layer(s). For example, a sputtering process, a spray coating process, and/or a plating process may be used to form the metal layer(s). The process of forming one or more interconnects may include desmearing, masking, mask removal, and/or etching.

### Exemplary Flow Diagram of a Method for Fabricating a Substrate

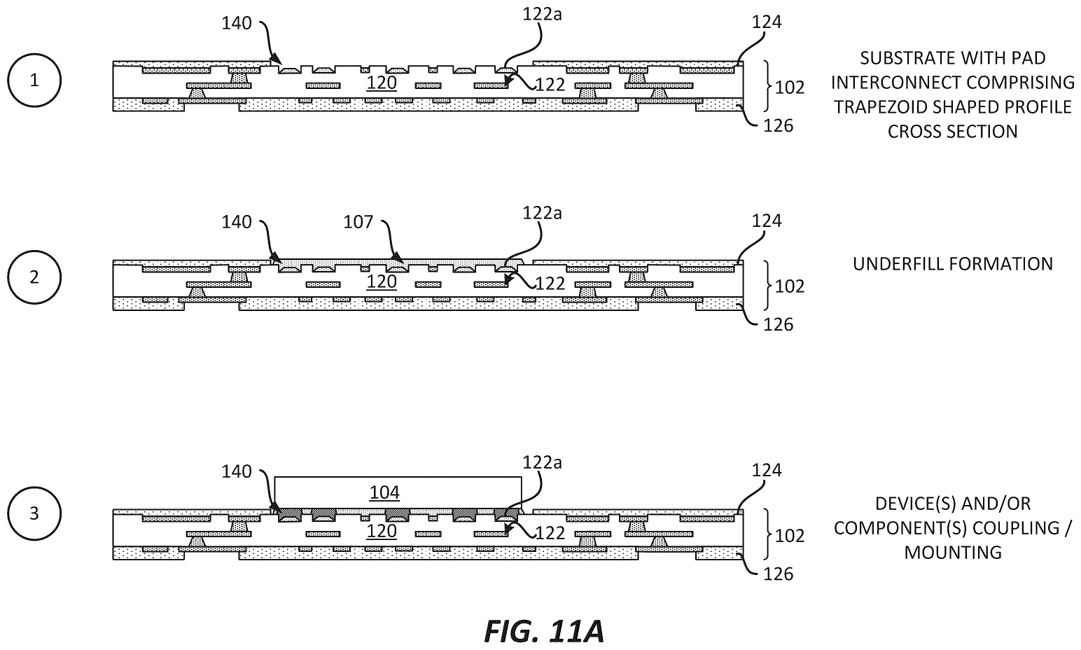

In some implementations, fabricating a substrate includes several processes. FIG. 10 illustrates an exemplary flow diagram of a method 1000 for providing or fabricating a substrate that includes a bump pad interconnect. In some implementations, the method 1000 of FIG. 10 may be used to provide or fabricate the substrate(s) of FIGS. 1 and 3-8. For example, the method 1000 of FIG. 10 may be used to fabricate the substrate 102.

It should be noted that the method 1000 of FIG. 10 may combine one or more processes in order to simplify and/or clarify the method for providing or fabricating a substrate that includes a bump pad interconnect. In some implementations, the order of the processes may be changed or modified. As will be further described below, the method 1000 may describe an example of providing at least one dielectric layer and forming a plurality of interconnects, where forming the plurality of interconnects comprises forming a bump pad interconnect that includes a profile cross section comprising a trapezoid shape.

The method provides (at 1005) a carrier (e.g., 900). Different implementations may use different materials for the carrier 900. The carrier 900 may include a seed layer (e.g., 901). The seed layer 901 may include a metal (e.g., copper). The carrier may include a substrate, glass, quartz and/or carrier tape. Stage 1 of FIG. 9A illustrates and describes an example of a carrier with a seed layer that is provided.

The method forms and patterns (at 1010) interconnects over the carrier 900 and the seed layer 901. A metal layer may be patterned to form interconnects. A plating process may be used to form the metal layer and interconnects. In some implementations, the carrier and seed layer may include a metal layer. The metal layer is located over the seed layer and the metal layer may be patterned to form interconnects (e.g., 902). Stage 1 of FIG. 9A illustrates and describes an example of interconnects over a seed layer and a carrier.

The method forms/provides (at 1015) a dielectric layer 920 over the seed layer 901, the carrier 900 and the interconnects 902. A deposition and/or lamination process may be used to form the dielectric layer 920. The dielectric layer 920 may include prepreg and/or polyimide. The dielectric layer 920 may include a photo-imageable dielectric. Forming the dielectric layer 920 may also include forming a plurality of cavities (e.g., 910) in the dielectric layer 920. The plurality of cavities may be formed using an etching process (e.g., photo etching) and/or laser process. Stages 2-3 of FIG. 9A illustrate and describe an example of forming a dielectric layer and cavities in the dielectric layer.

The method forms (at 1020) interconnects in and over the dielectric layer. For example, the interconnects 912 may be formed in and over the dielectric layer 920. A plating process may be used to form the interconnects. Forming interconnects may include providing a patterned metal layer over and/or in the dielectric layer. Forming interconnects may also include forming interconnects in cavities of the dielectric layer. Stage 4 of FIG. 9A illustrates and describes an example of interconnects formed in and over a dielectric layer.

The method forms/provides (at 1025) a dielectric layer 922 over the dielectric layer 920 and the interconnects 912. A deposition and/or lamination process may be used to form the dielectric layer 922. The dielectric layer 922 may include prepreg and/or polyimide. The dielectric layer 922 may include a photo-imageable dielectric. Forming the dielectric layer 922 may also include forming a plurality of cavities (e.g., 930) in the dielectric layer 922. The plurality of cavities may be formed using an etching process (e.g., photo etching) and/or laser process. Stages 5-6 of FIGS. 9A-9B illustrate and describe an example of forming a dielectric layer and cavities in the dielectric layer.

The method forms (at 1030) interconnects in and over the dielectric layer. For example, the interconnects 914 may be formed in and over the dielectric layer 922. A plating process may be used to form the interconnects. Forming interconnects may include providing a patterned metal layer over and/or in the dielectric layer. Forming interconnects may also include forming interconnects in cavities of the dielectric layer. Stage 7 of FIG. 9B illustrates and describes an example of forming interconnects in and over a dielectric layer.

The method decouples (at 1035) the carrier (e.g., 900) from the seed layer (e.g., 901). The carrier 900 may be detached and/or grounded out. The method may also remove (at 1035) portions of the seed layer (e.g., 901). An etching process may be used to remove portions of the seed layer 901. Decoupling the carrier 900 and the seed layer 901 leaves the substrate 102 that includes the at least one dielectric layer 120 and the plurality of interconnects 122. Some of the interconnects from the plurality of interconnects 122 may be located in cavities of the at least one dielectric layer 120. For example, the bump pad interconnect 122a may be located in a cavity of the at least one dielectric layer 120. The cavity is formed through a first surface of the at least one dielectric layer 120. The bump pad interconnect 122a may have the same width as the width of the cavity. The bump pad interconnect 122a may be recessed from the top surface of the at least one dielectric layer 120. Stage 8 of FIG. 9B, illustrates and describes an example of decoupling a carrier and seed layer removal.

The method provides (at 1040) a mask (e.g., 940) over the at least one dielectric layer 120 (e.g., a top surface of the at least one dielectric layer 120). A deposition and/or a lamination process may be used to form the mask 940 over a surface of the at least one dielectric layer 120. A mask 940 may be formed over a portion of the bump pad interconnect 122a, leaving portions of the bump pad interconnect 122a and portions of the bump pad interconnect 122a exposed. The mask 940 may include a dry film resist (DFS). Stage 9 of FIG. 9B, illustrates and describes an example of a mask/dry film resist that is provided over a dielectric layer of a substrate.

The method also removes (at 1040) portions of a bump pad interconnect (e.g., 122a). An etching process may be used to remove portions of the bump pad interconnect 122a. The etching process may include a chemical etching process. Different implementations may remove a different amount of the portion of the bump pad interconnect 122a. The etching process may include partial etching and/or full etching. The etching of the bump pad interconnect 122a (or any other bump pad interconnects) may form and define a bump pad interconnect that includes a trapezoid shaped cross section (e.g., bump pad interconnect that includes a profile cross section that has a shape of trapezoid), as described above in at least FIGS. 2-8. Stage 10 of FIG. 9C, illustrates and describes an example of portions of a bump pad interconnect that have been removed.

The method removes (at 1045) the mask (e.g., 940) from the at least one dielectric layer 120. A decoupling process may be used to remove the mask 940. Stage 11 of FIG. 9C, illustrates and describes an example of a mask that is removed.

The method forms (at 1050) solder resist layer(s) over the at least one dielectric layer (e.g., 120). A deposition process may be used to form the solder resist layer 124 and/or the solder resist layer 126. Stage 12 of FIG. 9C, illustrates and describes an example of solder resist layers formed over a dielectric layer.

Different implementations may use different processes for forming the metal layer(s). In some implementations, a chemical vapor deposition (CVD) process and/or a physical vapor deposition (PVD) process for forming the metal layer(s). For example, a sputtering process, a spray coating process, and/or a plating process may be used to form the metal layer(s). The process of forming one or more interconnects may include desmearing, masking, mask removal, and/or etching.

Exemplary Sequence for Fabricating a Package Comprising a Substrate with a Bump Pad Interconnect with a Profile Cross Section Having a Trapezoid Shape

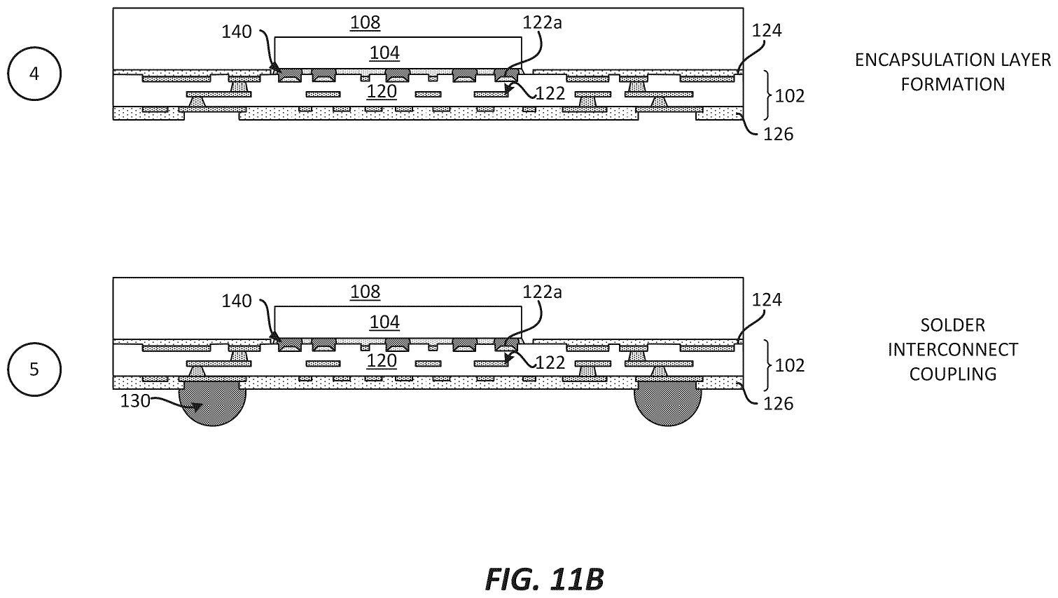

In some implementations, fabricating a package includes several processes. FIGS. 11A-11B illustrate an exemplary sequence for providing or fabricating a package that includes a substrate with bump pad interconnects. In some implementations, the sequence of FIGS. 11A-11B may be used to provide or fabricate the package 100. However, the process of FIGS. 11A-11B may be used to fabricate any of the packages described in the disclosure.

It should be noted that the sequence of FIGS. 11A-11B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 11A illustrates a state after a substrate 102 is provided. The substrate 102 includes at least one dielectric layer 120, a plurality of interconnects 122 (including a bump pad interconnect 122a with a trapezoid shaped profile cross section), a solder resist layer 124, and a solder resist layer 126. Different implementations may use different substrates with different numbers of metal layers. The substrate 102 may be fabricated using the method as described in FIGS. 9A-9C.

Stage 2 illustrates a state after an underfill 107 is provided over a surface of the substrate 102. The underfill 107 may include non-conducting paste (NCP).

Stage 3 illustrates a state after the integrated device 104 is coupled to the substrate 102 through the plurality of solder interconnects 140. A solder reflow process may be used to couple the integrated device 104 to the substrate 102. A thermal compression (TC) bonding process may be used to couple the integrated device 104 to the bump pad interconnect 122a of the substrate 102. The integrated device 104 may be coupled to the first surface (e.g., top surface) of the substrate 102. The integrated device 104 may be coupled to the bump pad interconnect 122a of the substrate 102 through a solder interconnect from a plurality of solder interconnects 140.

Stage 4, as shown in FIG. 11B, illustrates a state after an encapsulation layer 108 is provided (e.g., formed) over the first surface of the substrate 102. The encapsulation layer 108 is coupled to the substrate 102. The encapsulation layer 108 may encapsulate the integrated device 104. The encapsulation layer 108 may include a mold, a resin and/or an epoxy. A compression molding process, a transfer molding process, or a liquid molding process may be used to form the encapsulation layer 108. The encapsulation layer 108 may be photo etchable. The encapsulation layer 108 may be a means for encapsulation.

Stage 5 illustrates a state after a plurality of solder interconnects 130 are coupled to the substrate 102. A solder reflow process may be used to couple the plurality of solder interconnects 130 to the substrate 102. The plurality of solder interconnects 130 may be coupled to the plurality of interconnects 122 of the substrate 102.

The packages (e.g., 100) described in the disclosure may be fabricated one at a time or may be fabricated together as part of one or more wafers and then singulated into individual packages.

Exemplary Flow Diagram of a Method for Fabricating a Package Comprising a Substrate with a Bump Pad Interconnect with a Profile Cross Section Having a Trapezoid Shape

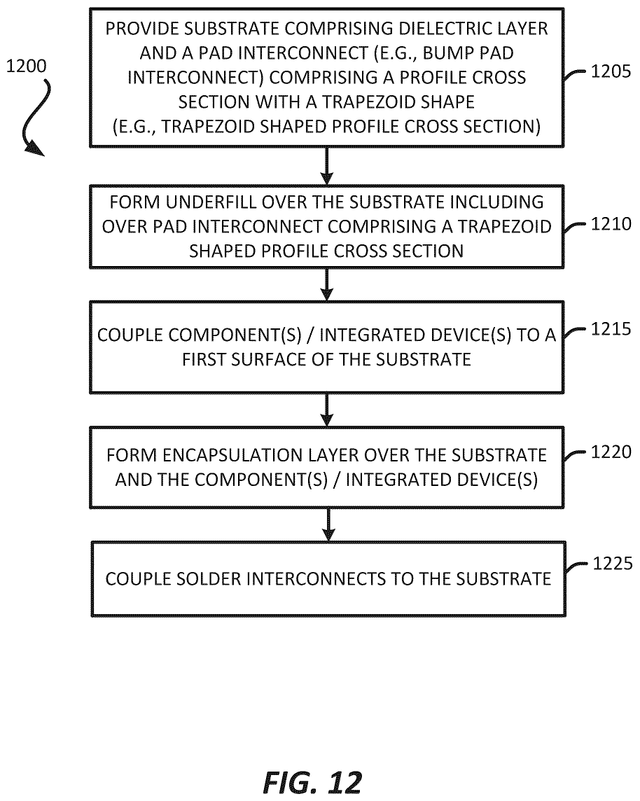

In some implementations, fabricating a package includes several processes. FIG. 12 illustrates an exemplary flow diagram of a method 1200 for providing or fabricating a package. In some implementations, the method 1200 of FIG. 12 may be used to provide or fabricate the package 100 of FIG. 1.

It should be noted that the method 1200 of FIG. 12 may combine one or more processes in order to simplify and/or clarify the method for providing or fabricating a package. In some implementations, the order of the processes may be changed or modified.

The method provides (at 1205) a substrate (e.g., 102). The substrate 102 includes at least one dielectric layer 120, a plurality of interconnects 122 (including a bump pad interconnect 122a with a trapezoid shaped profile cross section), a solder resist layer 124, and a solder resist layer 126. Different implementations may use different substrates with different numbers of metal layers. The substrate 102 may be fabricated using the method as described in FIGS. 9A-9C. Stage 1 of FIG. 11A, illustrates and describes an example of providing a substrate.

The method forms (at 1210) an underfill (e.g., 107) over the substrate, including over a bump pad interconnect that includes a trapezoid shaped profile cross section. The underfill 107 that is formed and/or provided may include a non-conducting paste. Stage 2 of FIG. 11A, illustrates and describes an example of providing an underfill.

The method couples (at 1215) components and/or integrated device(s) to the substrate. For example, the method may couple the integrated device 104 to the substrate 102 through a plurality of solder interconnects 140. A solder reflow process may be used to couple the integrated device 104 to the substrate 102. A thermal compression (TC) bonding process may be used to couple the integrated device 104 to the bump pad interconnect 122a of the substrate 102. The integrated device 104 may be coupled to the first surface (e.g., top surface) of the substrate 102. The integrated device 104 may be coupled to at least one bump pad interconnect 122a of the substrate 102 through a solder interconnect from a plurality of solder interconnects 140. Stage 3 of FIG. 11A, illustrates and describes an example of coupling an integrated device to a substrate.

The method forms (at 1220) an encapsulation layer (e.g., 108) over the substrate 102 and the integrated device 104. The encapsulation layer 108 may encapsulate the integrated device 104. The encapsulation layer 108 may include a mold, a resin and/or an epoxy. A compression molding process, a transfer molding process, or a liquid molding process may be used to form the encapsulation layer 108. The encapsulation layer 108 may be photo etchable. The encapsulation layer 108 may be a means for encapsulation. Stage 4 of FIG. 11B, illustrates and describes an example of forming an encapsulation layer.

The method couples (at 1225) a plurality of solder interconnects (e.g., 130) to the substrate 102. A solder reflow process may be used to couple the plurality of solder interconnects 130 to the substrate 102. The plurality of solder interconnects 130 may be coupled to the plurality of interconnects 122. Stage 5 of FIG. 11B, illustrates and describes an example of coupling solder interconnects to a substrate.

The packages (e.g., 100) described in the disclosure may be fabricated one at a time or may be fabricated together as part of one or more wafers and then singulated into individual packages.

### Exemplary Electronic Devices

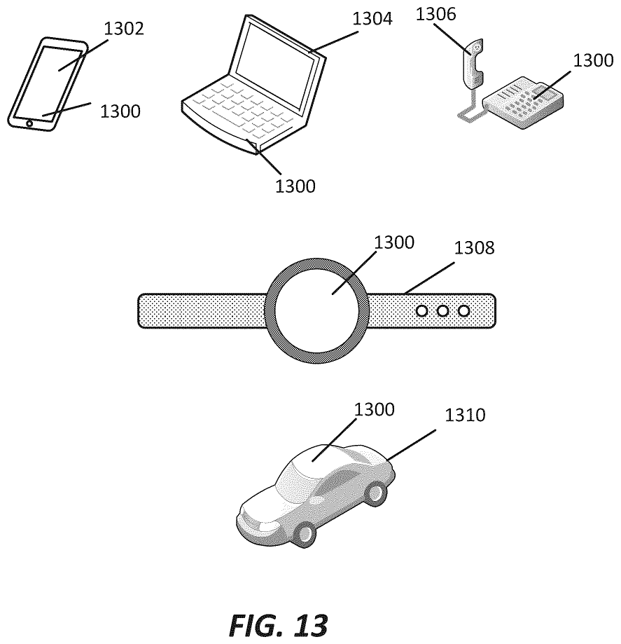

FIG. 13 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-8, 9A-9C, 10, 11A-11B and/or 12-13 may be rearranged and/or combined into a single component, process, feature or function or embodied in several components, processes, or functions. Additional elements, components, processes, and/or functions may also be added without departing from the disclosure. It should also be noted FIGS. 1-8, 9A-9C, 10, 11A-11B and/or 12-13 and its corresponding description in the present disclosure is not limited to dies and/or ICs. In some implementations, FIGS. 1-8, 9A-9C, 10, 11A-11B and/or 12-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. There may or may not be one or more interfaces between interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects. The process of forming one or more interconnects may include desmearing, masking, mask removal, and/or etching.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising a substrate and an integrated device coupled to the substrate. The substrate includes at least one dielectric layer and a plurality of interconnects comprising a bump pad interconnect, where the bump pad interconnect comprises a profile cross section that has a trapezoid shape.

Aspect 2: The package of aspect 1, wherein the integrated device is coupled to the substrate through the bump pad interconnect and a solder interconnect.

Aspect 3: The package of aspects 1 through 2, wherein the bump pad interconnect includes a diagonal surface, the diagonal surface is diagonal relative to a surface of the at least one dielectric layer.

Aspect 4: The package of aspects 1 through 3, wherein the bump pad interconnect is located in a cavity of the at least one dielectric layer.

Aspect 5: The package of aspect 4, wherein the bump pad interconnect has a top portion and a bottom portion, wherein the top portion of the bump pad interconnect is located in the cavity, and wherein the top portion is recessed from a surface of the at least one dielectric layer.

Aspect 6: The package of aspect 5, wherein the bottom portion of the bump pad interconnect is free of direct contact with a side wall of the cavity of the at least one dielectric layer.

Aspect 7: The package of aspects 5 through 6, wherein the top portion of the bump pad interconnect is free of direct contact with a side wall of the cavity of the at least one dielectric layer, and wherein the bottom portion of the bump pad interconnect is in direct contact with a side wall of the cavity of the at least one dielectric layer.

Aspect 8: The package of aspects 5 through 7, wherein the cavity has a cavity width, and wherein the top portion of the bump pad interconnect has a top bump pad width that is less than the cavity width.

Aspect 9: The package of aspects 5 through 8, wherein the cavity has a cavity width, and wherein the bottom portion of the bump pad interconnect has a bottom hump pad width that is less than the cavity width.

Aspect 10: The package of aspects 5 through 9, further comprising an underfill located between the at least one dielectric layer and the integrated device.

Aspect 11: The package of aspect 10, wherein the underfill is located in the cavity.

Aspect 12: An apparatus comprising a package that includes a substrate and an integrated device coupled to the substrate. The substrate includes at least one dielectric layer comprising a cavity, wherein the cavity comprises a cavity width and a plurality of interconnects comprising a bump pad interconnect. The bump pad interconnect includes a first portion comprising a first width, wherein the first width is less than the cavity width and a second portion comprising a second width that is greater than the first width. The bump pad interconnect is located in the cavity of the at least one dielectric layer.

Aspect 13: The apparatus of aspect 12, wherein the integrated device is coupled to the substrate through the bump pad interconnect and a solder interconnect.

Aspect 14: The apparatus of aspects 12 through 13, wherein the bump pad interconnect includes a diagonal surface, the diagonal surface is diagonal relative to a surface of the at least one dielectric layer.

Aspect 15: The apparatus of aspects 12 through 14, wherein the first portion is a top portion, wherein the second portion is a bottom portion, wherein the top portion of the bump pad interconnect is located in the cavity, and wherein the top portion is recessed from a surface of the at least one dielectric layer.

Aspect 16: The apparatus of aspect 15, wherein the bottom portion of the bump pad interconnect is free of direct contact with a side wall of the cavity of the at least one dielectric layer.

Aspect 17: The apparatus of aspects 15 through 16, wherein the top portion of the bump pad interconnect is free of direct contact with a side wall of the cavity of the at least one dielectric layer, and wherein the bottom portion of the bump pad interconnect is in direct contact with a side wall of the cavity of the at least one dielectric layer.

Aspect 18: The apparatus of aspects 12 through 17, further comprising an underfill located between the at least one dielectric layer and the integrated device.

Aspect 19: The apparatus of aspect 18, wherein the underfill is located in the cavity.

Aspect 20: The apparatus of aspects 12 through 18, wherein the apparatus includes a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: A method for fabricating a substrate. The method provides at least one dielectric layer. The method forms a plurality of interconnects, where forming the plurality of interconnects comprises forming a bump pad interconnect that includes a profile cross section comprising a trapezoid shape.

Aspect 22: The method of aspect 21, wherein forming the bump pad interconnect comprises depositing a mask over the bump pad interconnect; etching a portion of the bump pad interconnect to form a diagonal surface on the bump pad interconnect, wherein the diagonal surface is diagonal relative to a surface of the at least one dielectric layer, and removing the mask.

Aspect 23: The method of aspect 22, wherein the mask comprises a dry film resist, and wherein etching the portion of the bump pad interconnect comprises a chemical etching of the portion of the bump pad interconnect.

Aspect 24: The method of aspects 21 through 23, wherein the bump pad interconnect has a top portion and a bottom portion, wherein the top portion and the bottom portion of the bump pad interconnect are located in a cavity of the at least one dielectric layer, wherein the top portion is recessed from a surface of the at least one dielectric layer, and wherein the bottom portion of the bump pad interconnect is free of direct contact with a side wall of the cavity of the at least one dielectric layer.

Aspect 25: The method of aspects 21 through 24, wherein the bump pad interconnect has a top portion and a bottom portion, wherein the top portion and the bottom portion of the bump pad interconnect are located in a cavity of the at least one dielectric layer, wherein the top portion of the bump pad interconnect is free of direct contact with a side wall of the cavity of the at least one dielectric layer, and wherein the bottom portion of the bump pad interconnect is in direct contact with a side wall of the cavity of the at least one dielectric layer.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising:
at least one dielectric layer; and
a plurality of interconnects comprising a bump pad interconnect, wherein the bump pad interconnect comprises a profile cross section that has a trapezoid shape; and
an integrated device coupled to the substrate.

2. The package of claim 1, wherein the integrated device is coupled to the substrate through the bump pad interconnect and a solder interconnect.

3. The package of claim 1,
wherein the bump pad interconnect includes a diagonal surface, and
wherein the diagonal surface is diagonal relative to a surface of the at least one dielectric layer.

4. The package of claim 1, wherein the bump pad interconnect is located in a cavity of the at least one dielectric layer.

5. The package of claim 4,
wherein the bump pad interconnect has a top portion and a bottom portion,
wherein the top portion of the bump pad interconnect is located in the cavity, and
wherein the top portion is recessed from a surface of the at least one dielectric layer.

6. The package of claim 5, wherein the bottom portion of the bump pad interconnect is free of direct contact with a side wall of the cavity of the at least one dielectric layer.

7. The package of claim 5,
wherein the top portion of the bump pad interconnect is free of direct contact with a side wall of the cavity of the at least one dielectric layer, and
wherein the bottom portion of the bump pad interconnect is in direct contact with the side wall of the cavity of the at least one dielectric layer.

8. The package of claim 5,
wherein the cavity has a cavity width, and
wherein the top portion of the bump pad interconnect has a top bump pad width that is less than the cavity width.

9. The package of claim 5,
wherein the cavity has a cavity width, and
wherein the bottom portion of the bump pad interconnect has a bottom bump pad width that is less than the cavity width.

10. The package of claim 5, further comprising an underfill located between the at least one dielectric layer and the integrated device.

11. The package of claim 10, wherein the underfill is located in the cavity.

12. An apparatus comprising:
a package comprising:
a substrate comprising:
at least one dielectric layer comprising a cavity, wherein the cavity comprises a cavity width; and
a plurality of interconnects comprising a bump pad interconnect, wherein the bump pad interconnect comprises:
a first portion comprising a first width, wherein the first width is less than the cavity width; and
a second portion comprising a second width that is greater than the first width,
wherein the bump pad interconnect is located in the cavity of the at least one dielectric layer; and
an integrated device coupled to the substrate.

13. The apparatus of claim 12, wherein the integrated device is coupled to the substrate through the bump pad interconnect and a solder interconnect.

14. The apparatus of claim 12,
wherein the bump pad interconnect includes a diagonal surface, and
wherein the diagonal surface is diagonal relative to a surface of the at least one dielectric layer.

15. The apparatus of claim 12,
wherein the first portion is a top portion,
wherein the second portion is a bottom portion,
wherein the top portion of the bump pad interconnect is located in the cavity, and
wherein the top portion is recessed from a surface of the at least one dielectric layer.

16. The apparatus of claim 15, wherein the bottom portion of the bump pad interconnect is free of direct contact with a side wall of the cavity of the at least one dielectric layer.

17. The apparatus of claim 15,
wherein the top portion of the bump pad interconnect is free of direct contact with a side wall of the cavity of the at least one dielectric layer, and
wherein the bottom portion of the bump pad interconnect is in direct contact with the side wall of the cavity of the at least one dielectric layer.

18. The apparatus of claim 12, further comprising an underfill located between the at least one dielectric layer and the integrated device.

19. The apparatus of claim 18, wherein the underfill is located in the cavity.

20. The apparatus of claim 12, wherein the apparatus includes a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

21. A method for fabricating a substrate, comprising:
providing at least one dielectric layer; and
forming a plurality of interconnects, wherein forming the plurality of interconnects comprises forming a bump pad interconnect that includes a profile cross section comprising a trapezoid shape.

22. The method of claim 21, wherein forming the bump pad interconnect comprises:
depositing a mask over the bump pad interconnect;
etching a portion of the bump pad interconnect to form a diagonal surface on the bump pad interconnect, wherein the diagonal surface is diagonal relative to a surface of the at least one dielectric layer, and
removing the mask.

23. The method of claim 22,
wherein the mask comprises a dry film resist, and
wherein etching the portion of the bump pad interconnect comprises a chemical etching of the portion of the bump pad interconnect.

24. The method of claim 21,
wherein the bump pad interconnect has a top portion and a bottom portion,
wherein the top portion and the bottom portion of the bump pad interconnect are located in a cavity of the at least one dielectric layer,
wherein the top portion is recessed from a surface of the at least one dielectric layer, and
wherein the bottom portion of the bump pad interconnect is free of direct contact with a side wall of the cavity of the at least one dielectric layer.

25. The method of claim 21,
wherein the bump pad interconnect has a top portion and a bottom portion,
wherein the top portion and the bottom portion of the bump pad interconnect are located in a cavity of the at least one dielectric layer,
wherein the top portion of the bump pad interconnect is free of direct contact with a side wall of the cavity of the at least one dielectric layer, and
wherein the bottom portion of the bump pad interconnect is in direct contact with the side wall of the cavity of the at least one dielectric layer.
